(19) United States
(12) Patent Application Publication
(10) Pub. No.: US 2025/0334620 A1
(43) Pub. Date: Oct. 30, 2025

(54) MEASUREMENT OF LOAD CAPACITANCE OR IMPEDANCE IN HIGH-VOLTAGE DC POWER SUPPLIES

(71) Applicant: Spellman High-Voltage Electronics Corporation, Hauppauge, NY (US)

(72) Inventor: Jean-Michel Seveau, Pullborough (GB)

(21) Appl. No.: 18/649,515

(22) Filed: Apr. 29, 2024

(51) Int. Cl. G01R 27/16; G01R 15/18; G01R 19/25; G01R 27/26; H02J 3/36

(52) U.S. Cl. CPC G01R 27/16; G01R 15/181; G01R 19/2513; G01R 27/2605; H02J 3/36

(57) ABSTRACT

A power supply comprises a current sensor that measures an oscillating current through a load connected to the power supply, a voltage sensor that measures an oscillating voltage across the load, and a source conductor that transmits the sinusoidal voltage generated by a sinewave oscillator. A micro-controller is coupled to the current sensor, the voltage sensor, and the source conductor. The micro-controller computes the impedance or capacitance of the load by using digital data derived from the three sensors.

### CROSS-REFERENCE TO RELATED APPLICATIONS

None

### FIELD OF THE INVENTION

The disclosure relates generally electric power supplies adapted for generating a direct current (DC) high-voltage, which are capable of monitoring the impedance or capacitance of loads connected to the power supplies. The disclosure relates more particularly to such electric power supplies that are suitable for use with electrostatic chucks.

### BACKGROUND OF THE INVENTION

In semiconductor and liquid crystal panel manufacturing processes, vacuum chucks and mechanical chuck systems have conventionally been used to secure the substrate for handling. However, due to the effects of adsorption, distortion and a requirement for improved reliability, chucks that utilize electrostatic force have been widely adopted in today's generation of semi fab equipment to overcome these limitations.

An electrostatic chuck (“e-chuck”) consists of a platen with surface electrodes which are biased with high voltage to set up an electrostatic force between the platen and the wafer. Two types of electrostatic chucks are available: the Coulomb and Johnsen-Rahbek (“J-R”) types. These are distinguished by their dielectric characteristics and, therefore, the way the clamping force is generated. A Coulomb chuck functions like a conventional dielectric capacitor. The J-R type has a large but finite resistance, so current flows through it and the substrate when the surfaces are in close contact and voltage is applied. Charge accumulates at the interface between substrate and dielectric which provides the clamping force.

In addition, different configurations of electrodes (or poles) on the chuck are used to get different characteristics. Monopolar, bipolar (two poles) and multipolar chucks (including 6 phase hexapolar types) are available depending on the application.

Known power supplies are provided for the complete range of e-chucks. The known power supplies have features that include:
high-voltage bipolar outputs (positive/negative),
output polarity reversal functions for easier wafer chucking/de-chucking,
capability to detect the state of the wafer by capacitance measurement (Coulomb chucks) or current measurement (J-R chucks), and/or
analogue and digital interfaces for easy integration into a variety of systems.

For example, a known power supply suitable for use with a Coulomb chuck is illustrated is FIG. 1. In this example, the power supply is bipolar and comprises two terminals 26a and 26b. A load 10, for example, a Coulomb-type electrostatic chuck, is shown connected between the two terminals 26a and 26b. In use, each of electric generators 12a and 12b generates a direct current (DC) high-voltage that is applied to the load 10.

The power supply shown in FIG. 1 comprises a sinewave oscillator 16. In use, the sinewave oscillator 16 generates a sinusoidal voltage at a predetermined frequency. The sinewave oscillator 16 is connected to a first lead of the capacitor 18 and the second lead of the capacitor 18 is connected to the terminal 26a. The sinusoidal voltage applied to the first lead of the capacitor 18 causes an oscillating current to flow from the ground. A first portion of this oscillating current may flow back to the ground via the blocking inductor 14a and the electric generator 12a. A second portion of this oscillating current may flow back to the ground via the load 10, the capacitor 22 and the current-to-voltage converter 20. A third portion of this oscillating current may flow back to the ground via the load 10, the blocking inductor 14b, and the electric generator 12b.

The first portion of the oscillating current is ideally negligible compared to the second portion of the oscillating current. In contrast, the second portion of the oscillating current is almost equal to the alternating current (AC) flowing through the load 10. Similar to the first portion, the third portion of the oscillating current is also ideally negligible compared to the second portion of the oscillating current.

Because load 10, blocking inductor 14a and coupling capacitor 18 are placed in parallel, an oscillating potential results at one lead of the load 10. Similarly, because load 10, blocking inductor 14b and coupling capacitor 22 are placed in parallel, an oscillating potential results at the other lead of the load 10.

The power supply shown in FIG. 1 comprises a first sensor that measures the magnitude of the second portion of the oscillating current, which is, as previously mentioned, almost equal to the AC flowing through the load 10. The first sensor includes the current-to-voltage converter 20, a full wave rectifier, a lowpass filter, and a channel of an analog-to-digital converter ADC 24a. The first sensor cannot measure phases.

The power supply shown in FIG. 1 comprises a second sensor that measure the magnitude of the sinusoidal voltage generated by the sinewave oscillator 16. The second sensor includes a full wave rectifier, a lowpass filter, and a channel of the ADC 24a. The second sensor cannot measure phases.

The power supply shown in FIG. 1 does not directly measure the voltage at the terminal 26, and the oscillation voltage caused by the flow of first and second portions of the oscillating current through the capacitor 18 can only be estimated.

The power supply shown in FIG. 1 comprises a micro-controller 24 that is programmed to estimate the capacitance of the load 10 from the digitized magnitude of the sinusoidal voltage, the magnitude of the AC current flowing through the load 10 (which is approximated by the magnitude of the second portion of the oscillating current) and the values of capacitors 18 and 22. In some cases, however, the estimate of the capacitance of the load 10 may lack accuracy and/or precision.

The power supply shown in FIG. 2 is bipolar. It has a terminal A⁺ and a terminal B⁻, each connected to the load 10. It comprises electric generators 12a and 12b, and a monitor 34.

In this example, the monitor 34 comprises a sinewave oscillator 16a and a transformer 16b for injecting a sinusoidal signal via capacitors 18a and 18b in a differential manner. Note that the circuit consisting of the sinewave oscillator 16a and the transformer 16b can be considered to form a sinewave oscillator in itself too: it generates the two voltage signals at the leads of the two secondary coils of the transformer 16b, and a third voltage signal R (e.g., a reference signal) between the two resistors connected in series with the two secondary coils. Blocking inductors 14a and 14b are used to increase the impedance of the electric generators 12a and 12b at the sinewave oscillator 16a frequency.

As a result of the combined actions of the sinewave oscillator consisting of the sinewave oscillator 16a and the transformer 16b, the capacitors 18a and 18b, and the blocking inductors 14a and 14b, a first, small, portion of an alternating current (i.e., without DC component) flows through the sinewave oscillator 16a/16b (including through the resistor 20a), the capacitor 18a, the blocking inductor 14a, the electric generators 12a and 12b, the blocking inductor 14b, the capacitor 18b and back to the sinewave oscillator 16a/16b. A second, larger, portion of the alternating current flows through the sinewave oscillator 16a/16b (including through the resistor 20a), the capacitor 18a, the load 10, the capacitor 18b, and back to the sinewave oscillator 16a/16b.

The alternating current flowing through the load 10 is measured using the floating sensor 21, which measures the voltage drop across the resistor 20a. The sensor 21 includes a voltage follower, a differential amplifier, and a filter (either the bandpass filter connected to signal I*GI and to circuit 32 and/or the bandpass filter connected to signal I*GI via a multiplexer and to circuit 33). This estimation can be used as the current flowing through the load 10 when the first and third portions of the alternating current are sufficiently small compared to the second portion, so that the voltage drop across the resistor 20a is mainly caused by the alternating current flowing through the load 10 (i.e., the second portion of the alternating current).

The AC component of the voltage at the terminal A⁺ is measured via the floating sensor 28, which includes a feedback capacitor, a voltage follower, a differential amplifier, and a filter (either the bandpass filter connected to signal V*GV and to circuit 32 or the bandpass filter connected to signal V*GV via a multiplexer and to circuit 33). The AC component of the voltage at the terminal B⁻ is assumed to be the opposite of the AC component of the voltage at the terminal A⁺.

Voltage V*GV, source S and current I*GI signals are fed to a demodulator 32, which provides an accurate way of calculating the phase of current and voltage. In this example, the demodulator 32 includes a pair of analog multipliers, each connected in series with a lowpass filter. Using V*GV, I*GI, and S analog signals, the demodulator 32 generates two analog signals: ½|V*GV|·|S|×COS φ(V*GV/S), and ½|I*GI|·|S|×COS φ(I*GI/S).

In this example, the monitor 34 also includes a rectifier 33, which, after lowpass filtering, generates one of the three analog signals: |V*GV|, |I*GI|, and |S|, depending on the status of the multiplexer.

A micro-controller 24 digitizes the two analog signals generated by the demodulator 32 and the three analog signals generated by the rectifier 33. The micro-controller 24 has known equations programmed in its firmware for calculating the capacitance/impedance of the load 10 from the digital data. In some cases, however, injecting a sinusoidal signal via capacitors 18a and 18b in a differential manner in a bipolar system may lack flexibility power supplies to be used with certain types of e-chucks.

The power supply shown in FIG. 3 represents one phase of a multipolar system. It has a terminal 26 connected to the load 10. It comprises an electric generator 12 and a monitor 34.

In this example, the monitor 34 comprises a sinewave oscillator 16 for adding a sinusoidal signal via a transformer 19 placed in series with the load. An RLC circuit 15, resonant at the frequency of the sinusoidal signal, is used to present a very low impedance path to ground to the injected AC current.

As a result of the combined actions of the sinewave oscillator 16, the transformer 19, and the RLC circuit 15, a first, small, portion of an alternating current (i.e., without DC component) flows in the HV generator 12. A second, larger, portion of the alternating current is supplied from the ground by the current-to-voltage converter 20 and flows through the RLC circuit 15, the secondary coil of the voltage transformer 19, the load 10 and back to the ground.

The alternating current flowing through the load 10 is estimated using a sensor which includes the current-to-voltage converter 20 and a filter (either the 90 deg lag filter connected to signal I*GI and to circuit 32 and/or the bandpass filter connected to signal I*GI and to circuit 33). This estimation can be used as the current flowing through the load 10 when the first portion of the alternating current is sufficiently small compared to the second portion.

The AC component of the voltage at the terminal of load 10 is estimated via the sensor 28, which is adapted for monitoring a voltage drop across the primary coil of the voltage transformer 19. The voltage sensor 28 includes an amplifier, and a filter (either the 90 deg lag filter connected to signal V*GV and to circuit 32 and/or the bandpass filter connected to signal V*GV and to circuit 33). This estimation can be used as the AC component of the voltage at the terminal of load 10 by using the ratio (e.g., 1:1) of voltage transformation of the voltage transformer 19.

Voltage V*GV, source S and current I*GI signals are fed to a demodulator 32, which provides an accurate way of calculating the phase of current and voltage. In this example, the demodulator 32 includes a pair of analog multipliers, each connected in series with a lowpass filter. Using V*GV, I*GI, and S analog signals, the demodulator 32 generates two analog signals: ½|V*GV|·|S|×COS φ(V*GV/S), and ½|I*GI|·|S|×COS φ(I*GI/S).

In this example, the monitor 34 also includes a rectifier 33, which, after lowpass filtering, generates three analog signals: |V*GV|, |I*GI|, and |S|.

A micro-controller 24 digitizes the two analog signals generated by the demodulator 32 and the three analog signals generated by the rectifier 33. The micro-controller 24 has known equations programmed in its firmware for calculating the capacitance/impedance of the load 10 from the digital data.

In view of the foregoing, there is a need in the art for a power supply capable of monitoring the impedance or capacitance of a load connected to the power supply.

### SUMMARY

The disclosure describes power supplies capable of monitoring the impedance or capacitance of a load connected to the power supply. The power supplies comprise a current sensor adapted for generating a first alternating signal indicative of an oscillating current through the load, a voltage sensor adapted for generating a second alternating signal indicative of an oscillating voltage across the load, and a source conductor adapted for transmitting a third alternating signal indicative of the sinusoidal voltage generated by a sinewave oscillator. A micro-controller is coupled to the first alternating signal, the second alternating signal, and the third alternating signal. The micro-controller is adapted for computing the impedance or capacitance of the load by using digital data derived from the first alternating signal, the second alternating signal, and the third alternating signal.

The invention is susceptible to various modifications and alternative forms, and specific embodiments thereof are shown by way of example in the drawings and description. It should be understood, however, that the drawings and description are not intended to limit the invention to the particular form disclosed, but on the contrary, the intention is to cover all modifications, equivalents, and alternatives available to a person having ordinary skill in the art.

### BRIEF DESCRIPTION OF THE DRAWINGS

For a more detailed description of the embodiments of the disclosure, reference will now be made to the accompanying drawings, wherein:

FIG. 1 is a schematic of a known bipolar power supply suitable for use with a Coulomb chuck;

FIG. 2 is a schematic of a known bipolar power supply suitable for use with a Coulomb chuck;

FIG. 3 is a schematic of a known one phase or one of multiple phases of a power supply suitable for use with a Coulomb chuck; and

FIG. 4 is a schematic of one phase or one of multiple phases of a power supply suitable for use with a Coulomb chuck.

### DETAILED DESCRIPTION

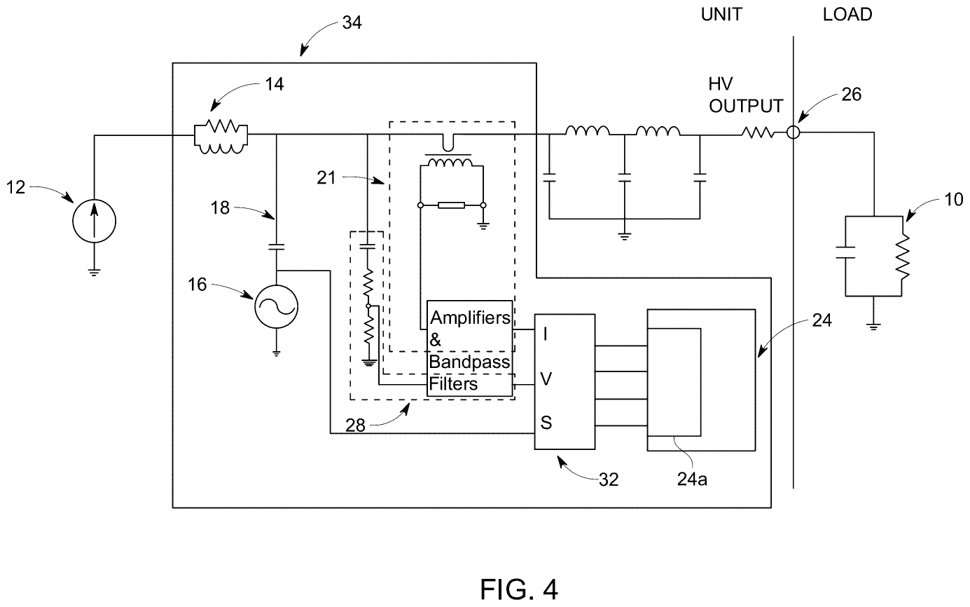

FIG. 4 illustrates preferred embodiments of a power supply having a monitor capable of causing voltage oscillations across a load connected to the power supply and current voltage oscillations into the load from a predetermined sinusoidal signal. The monitor is also capable of measuring, exactly or approximately,
the sinusoidal signal,
the amplitude and the phase shift relative to the sinusoidal signal of the voltage caused by the sinusoidal signal, and
the amplitude and the phase shift relative to the sinusoidal signal of the current caused by the sinusoidal signal.
   The monitor calculates the capacitance or impedance of the load based on the measurements.

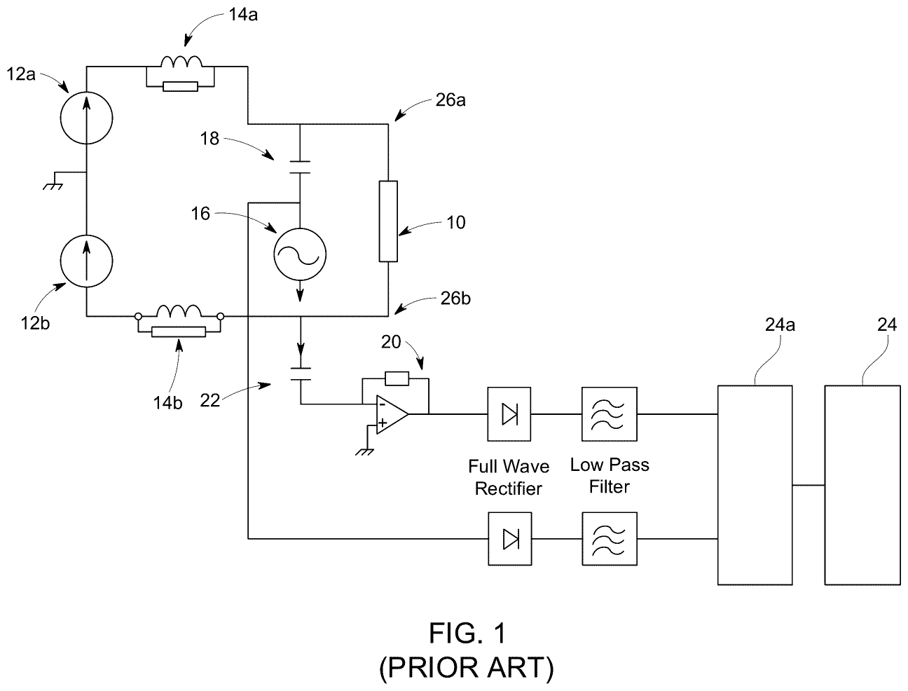

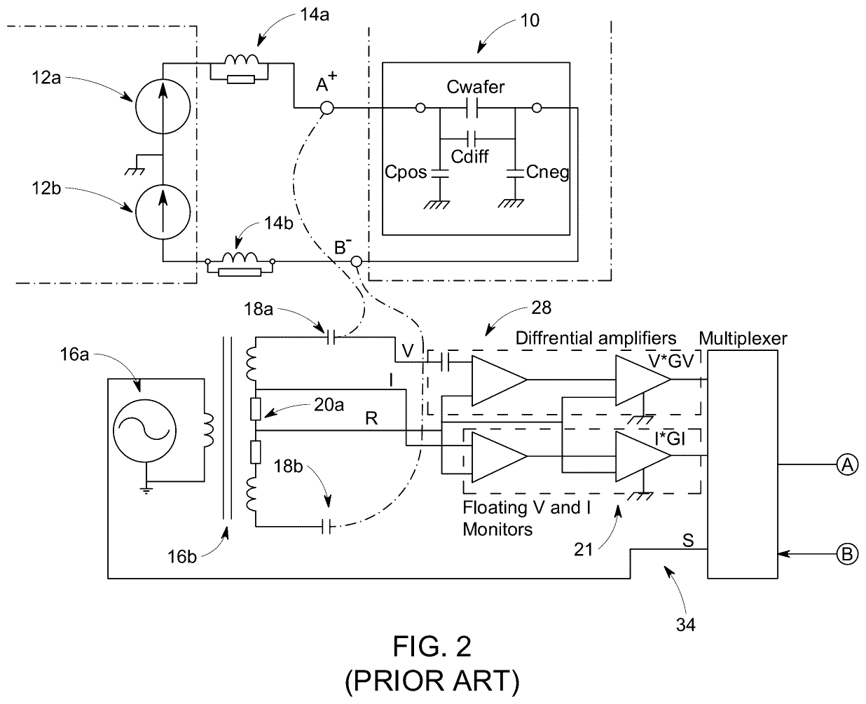

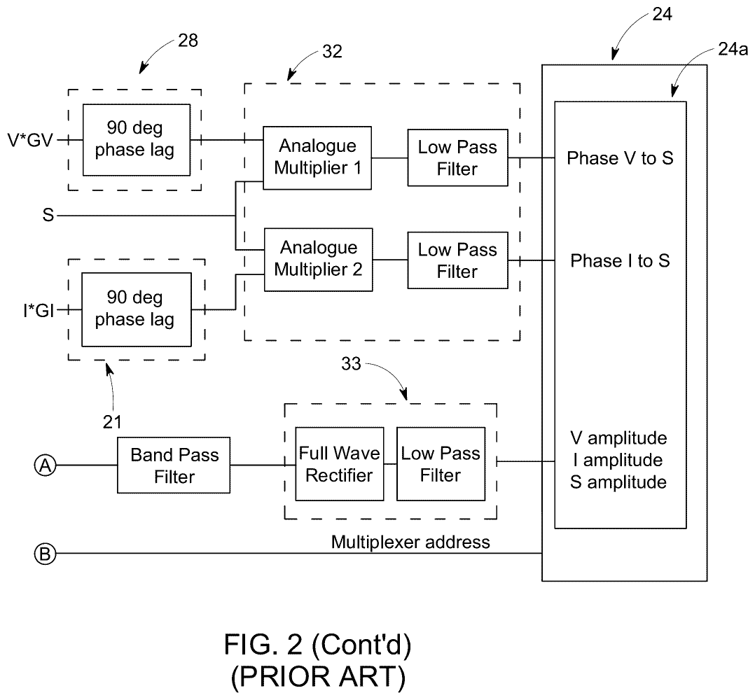

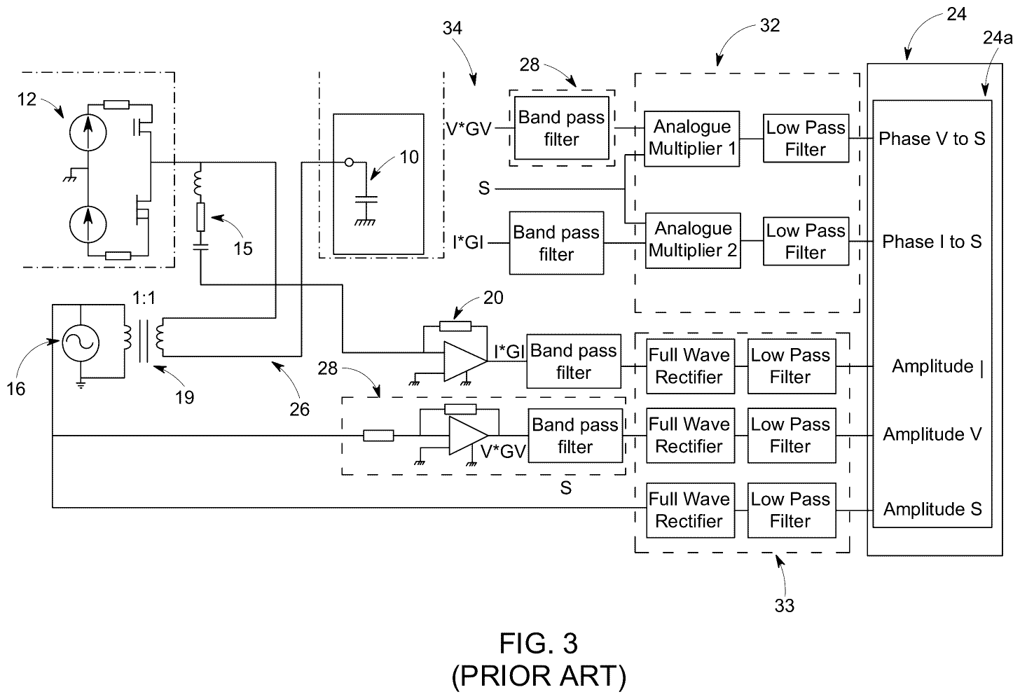

The preferred embodiments may provide simpler and more efficient ways of calculating the capacitance or impedance of the load than the power supplies illustrated in FIGS. 1-3.

The power supply shown in FIG. 4 is unipolar or one of multiple phases. It has a terminal 26 connected to the load 10. It comprises an electric generator 12 and a monitor 34.

In this example, the monitor 34 comprises a sinewave oscillator 16 for injecting a sinusoidal signal via a capacitor 18. A blocking inductor 14 is used to increase the impedance of the electric generator 12 at the sinewave oscillator 16 frequency.

As a result of the combined actions of the sinewave oscillator 16, the capacitor 18, and the blocking inductor 14, a first, small, portion of an alternating current (i.e., without DC component) flows through the sinewave oscillator 16, the capacitor 18, the blocking inductor 14, the electric generator 12, and back to the ground. A second, larger, portion of the alternating current, flows through the sinewave oscillator 16, the capacitor 18, the load 10, and back to the ground. A third, small, portion of the alternating current flows through the sinewave oscillator 16, the capacitor 18, a sensor 28, and back to the ground.

The second portion of the alternating current is measured using a sensor 21, which includes a current transformer (also providing high-voltage insulation), an amplifier, a filter. This second portion of the alternating current is the exact alternating component of the current flowing through the load 10.

The AC component of the voltage at the terminal 26 is measured via the sensor 28, which includes a capacitor, a voltage divider, an amplifier, and a filter. This measurement can be used as the AC component of the voltage at the terminal 26 as the voltage differential caused by the primary coil of the current transformer of the sensor 21 is negligible.

Voltage V, source S and current I signals are fed to a quadrature demodulator 32, which provides an accurate way of calculating amplitude and phase of current and voltage. Using analog V, I, and S signals, the demodulator 32 generates four analog signals: |V|·COS φ(V/S), [V]·SIN φ(V/S), [I]·COS φ(I/S) and |I|·SIN φ(I/S).

A micro-controller 24 digitizes the four signals with an ADC 24a. The micro-controller 24 has known equations programmed in its firmware for calculating the capacitance/impedance of the load 10 from the digital data.

Multiple monitors 34 can be used in multipolar power supplies having an architecture similar to the power supply shown in FIG. 4, each measuring capacitances/impedances to ground on multiple terminals. In such cases, differential capacitances/impedances can also be calculated, for example, by using a combination of different sensors on different terminals.

In addition to the foregoing, the disclosure also contemplates at least the following embodiments 1-14. It should be noted that any element of any of these embodiments may further include details related to this element that are disclosed in a paragraph or Figure describing the preferred embodiments without including details of other elements that are disclosed in the same or other paragraph or Figure.

### Embodiment 1

Embodiment 1 is a power supply capable of monitoring the impedance or capacitance of a load connected to the power supply.

The power supply includes at least a first terminal connectable to the load. The power supply also includes at least one electric generator that generates a direct current (DC) high-voltage between first and second terminals.

If only one electric generator is used, the power supply is unipolar. In such a case, the first terminal of the electric generator is connected to the first terminal of the power supply, and the second terminal of the electric generator is connected to the ground.

If two electric generators are used, the power supply can be bipolar. In such a case, the power supply further includes a second terminal. The first terminal of the first electric generator is again connected to the first terminal of the power supply, and the second terminal of the first electric generator is again connected to the ground. In addition, the first terminal of the second electric generator may be connected to ground, and the second terminal of the second electric generator is connected to the second terminal of the power supply.

The power supply is characterized by a monitor that comprises a inject circuit, a boost circuit, and a sinewave oscillator. When the power supply is bipolar, the monitor may comprise another boost circuit.

The inject circuit is adapted for flowing an oscillating current between first and second terminals. The first terminal of the inject circuit is connected to the first terminal of the power supply, and the second terminal of the inject circuit is connected to the ground or, if provided, the second terminal of the power supply. As such, the inject circuit is connected to the electric generator(s) in parallel with the load.

The boost circuit is adapted for generating an oscillating voltage between first and second terminals. The first terminal of the boost circuit is connected to the first terminal of the first electric generator and the second terminal of the boost circuit is connected to the first terminal of the power supply. The other boost circuit, if provided, may be connected between the second terminal of the second electric generator and the second terminal of the power supply. As such, the boost circuit(s) is (are) connected to the electric generator(s) in series with the load.

The sinewave oscillator is adapted for generating a sinusoidal voltage at a predetermined frequency. In contrast to a voltage having a different frequency spectrum, a sinusoidal voltage is preferred in cases where the load has an impedance that is frequency dependent, as is the case of the impedance of a capacitive circuit (e.g., an e-chuck). As such, the load response to a sinusoidal signal at a predetermined frequency is easier to interpret. However, the sinewave oscillator may be adapted for sequentially generating a sinusoidal voltage at a first predetermined frequency and then a sinusoidal voltage at a second, different predetermined frequency, etc. The sinewave oscillator is coupled to one of the inject circuit and the boost circuit. When the sinewave oscillator is coupled to the inject circuit, it drives the oscillating current, which flows through the load. The boost circuit(s) passively generate(s) the oscillating voltage, which tends to counteract the oscillating current so that less oscillating current flows through the electric generator(s). When the sinewave oscillator is coupled to the boost circuit, it drives the oscillating voltage, which is applied to the load. The inject circuit(s) passively generate the oscillating current, which tends to counteract the oscillating current that is generated by the load in response to the oscillating voltage and would otherwise flows through the electric generator(s) so that, again, less oscillating current flows through the electric generator(s).

The power supply is further characterized by a current sensor, a voltage sensor, and a source conductor, which each generates alternating signals used by a micro-controller for computing the impedance or capacitance of the load.

The current sensor is adapted for generating a first alternating signal indicative of the oscillating current. Generally, the current sensor may be adapted to convert a current flowing through the inject circuit or through the first terminal of the power supply into a voltage.

The voltage sensor is adapted for generating a second alternating signal indicative of the oscillating voltage. Generally, the voltage sensor may not be sensitive to the DC high-voltage generated by the electric generator(s).

The source conductor is adapted for transmitting a third alternating signal indicative of the sinusoidal voltage generated by the sinewave generator.

The micro-controller may be integral to the power supply or may be provided as a separate module. The micro-controller is coupled to the first alternating signal, the second alternating signal, and the third alternating signal. Optionally, the micro-controller may be sequentially coupled to the first, second, and third signals via a multiplexer. Alternatively, the micro-controller may be simultaneously coupled to the signals. The coupling of the micro-controller to the signals may be a direct digitized communication of the three alternating signals to the micro-controller, or an indirect digitized communication of other signals derived from the three alternating signals to the micro-controller. For example, the other signals may be derived by analog demodulations, rectification, filtering (e.g., bandpass filtering at the predetermined frequency), or combinations thereof.

Furthermore, the micro-controller is adapted for computing the impedance or capacitance of the load from digital data derived from the first alternating signal, the second alternating signal, and the third alternating signal. Typically, the micro-controller may be programmable and the computation of the impedance or capacitance of the load may be pre-programmed to implement mathematical formula well known in the art.

Notably, the use of the third alternating signal or alternating signals derived from the third alternating signal may advantageously improve the accuracy and/or precision of the computation of the impedance or capacitance of the load, typically in the presence of noise in the direct current (DC) high-voltage.

### Embodiment 2

Embodiment 2 is a power supply as described in embodiment 1, wherein:
(i) the inject circuit includes a coupling capacitor having one lead connected to the first terminal of the power supply,
(ii) the boost circuit includes a blocking inductor, and optionally, a bypass resistor,
(iii) the sinewave oscillator has a first terminal connected to another lead of the coupling capacitor and a second terminal connected to the second terminal of the power supply or the ground, and
(iv) the blocking inductor is connected between the first terminal of the electric generator and the coupling capacitor.

### Embodiment 3

Embodiment 3 is a power supply as described in embodiment 1, wherein:
(i) the inject circuit includes an LC circuit resonant at the predetermined frequency, or optionally, an RLC circuit resonant at the predetermined frequency, wherein the inject circuit has a first terminal connected to the first terminal of the power supply, and wherein the inject circuit has a second terminal connected to the second terminal of the power supply or the ground;
(ii) the boost circuit includes a transformer having a secondary winding connected between the first terminal of the electric generator and the first terminal of the power supply;
(iii) the sinewave oscillator is connected to a primary winding of the transformer, and
(iv) the first terminal of the RLC circuit is connected between the first terminal of the electric generator and the secondary winding of the transformer.

### Embodiment 4

Embodiment 4 is a power supply as described in any of embodiments 1 to 3, wherein the monitor further comprises an analog demodulator.

The analog demodulator has inputs coupled to the current sensor, the voltage sensor, and the source conductor. The analog demodulator has outputs coupled to the micro-controller.

The analog demodulator is configured to analogically demodulate the first alternating signal and the second alternating signal relative to the third alternating signal. In other words, the outputs of the analog demodulator are analog signals that may have a constant polarity and an amplitude indicative of either the phase difference between the first alternating signal and the third alternating signal, or the phase difference between the second alternating signal and the third alternating signal. For example, the outputs of the analog demodulator may have an amplitude proportional to the cosine or the sine of either the phase difference between first and third signals or the phase difference between second and third signals. Notably, the use of the analog demodulator may advantageously simplify the digitization of the signals before their use by the micro-controller.

Optionally, the monitor may also include one or more rectifier(s) having input(s) coupled to the first alternating signal, the second alternating signal, and/or the third alternating signal.

Typically, the outputs of the analog demodulator and the one or more rectifier(s) are lowpass filtered and digitized by a converter (i.e., an ADC). The digitized signals are then communicated to the micro-controller.

### Embodiment 5

Embodiment 5 is a power supply as described in embodiment 4 wherein the analog demodulator includes a quadratic demodulator.

The quadratic demodulator configured to generate four output signals:
(i) the magnitude of the first alternating signal multiplied by the cosine of the phase of the first alternating signal relative to the third alternating signal,
(ii) the magnitude of the first alternating signal multiplied by the sinus of the phase of the first alternating signal relative to the third alternating signal,
(iii) the magnitude of the second alternating signal multiplied by the cosine of the phase of the second alternating signal relative to the third alternating signal, and
(iv) the magnitude of the second alternating signal multiplied by the sinus of the phase of the second alternating signal relative to the third alternating signal.

In this embodiment, the one or more rectifier(s) may be omitted.

### Embodiment 6

Embodiment 6 is a power supply as described in embodiment 4 wherein the analog demodulator includes a first analog multiplier, a first lowpass filter in series with the first analog multiplier, a second analog multiplier, and a second lowpass filter in series with the second analog multiplier.

The first analog multiplier is configured to generate the product of the first alternating signal by the third alternating signal. Similarly, the second analog multiplier is configured to generate the product of the second alternating signal by the third alternating.

In this embodiment, the monitor further comprises one or more rectifier(s) each connected in series with a corresponding lowpass filter. The one or more rectifier(s) are connectable to one or more of the first alternating signal, the second alternating signal, and the third alternating signal (e.g., directly or via a multiplexer).

### Embodiment 7

Embodiment 7 is a power supply as described in any of embodiments 1 to 6, wherein the current sensor includes a current transformer having a primary coil in series between the boost circuit and the first terminal of the power supply and a secondary coil connected to a resistor and an input of an operational amplifier. The operational amplifier is wired as an inverting or non-inverting operational amplifier having a fixed gain. As used herein, “inverting operational amplifier” and “or non-inverting operational amplifier” are terms of art that refer to well-known configurations.

### Embodiment 8

Embodiment 8 is a power supply as described in any of embodiments 1 to 6, wherein the inject circuit includes a resistor through which the oscillating current flows and wherein the current sensor is adapted for monitoring a voltage drop across the resistor. Typically, the current sensor includes a first operational amplifier having an input connected to the high side of the resistor and wired as a voltage follower and a second operational amplifier having an input connected to the output of the first operational amplifier and wired as a differential amplifier. As used herein, “voltage follower” and “differential amplifier” are terms of art that refer to well-known configurations.

### Embodiment 9

Embodiment 9 is a power supply as described in any of embodiments 1 to 6, wherein the current sensor includes an operational amplifier having an input connected in series in the inject circuit, wherein the operational amplifier is wired as a current-to-voltage converter. As used herein, “current-to-voltage converter” is a term of art that refers to a well-known configuration.

### Embodiment 10

Embodiment 10 is a power supply as described in any of embodiments 1 to 9, wherein the voltage sensor includes a lowpass or bandpass filter connected to the first terminal of the power supply and to the ground, and an inverting or non-inverting operational amplifier having an input connected to the lowpass or bandpass filter. Preferably, the lowpass or bandpass filter has a high impedance (i.e., an impedance substantially higher than the impedance of the inject circuit), so that the voltage sensor draws a negligible current.

For example, the voltage sensor may include a feedback capacitor connected to the first terminal of the power supply, and an operational amplifier having an input connected, directly or indirectly via a resistor, to the feedback capacitor. Typically, the operational amplifier is wired as an inverting or non-inverting operational amplifier having a fixed gain. As used herein, “inverting operational amplifier” and “or non-inverting operational amplifier” are terms of art that refer to well-known configurations. Furthermore, the input of operational amplifier may be connected to the ground via another resistor.

### Embodiment 11

Embodiment 11 is a power supply as described in any of embodiments 1 to 9, wherein the voltage sensor includes a feedback capacitor connected to the first terminal of the power supply, a first operational amplifier connected to the feedback capacitor and wired as a voltage follower, and a second operational amplifier connected to an output of the first operational amplifier and wired as a differential amplifier. As used herein, “voltage follower” and “differential amplifier” are terms of art that refer to well-known configurations.

### Embodiment 12

Embodiment 12 is a power supply as described in any of embodiments 1 to 9, wherein the boost circuit includes a transformer having a secondary coil in series between the inject circuit and the first terminal of the power supply and a primary coil, and wherein the voltage sensor is adapted for monitoring a voltage drop across the primary coil. Typically, the voltage sensor includes an operational amplifier wired as an inverting or non-inverting operational amplifier having a fixed gain. As used herein, “inverting operational amplifier” and “or non-inverting operational amplifier” are terms of art that refer to well-known configurations.

For example, the transformer may be a 1:1 transformer. In this case, the oscillating voltage is in a 1:1 ratio with the voltage monitored by the voltage sensor before the amplifier gain is applied.

### Embodiment 13

Embodiment 13 is method of monitoring the impedance or capacitance of a load connected to a power supply. The method comprises the steps of providing the power supply of any of embodiments 1 to 12 and causing the monitor to display or store digital data indicative of the impedance or capacitance of the load.

### Embodiment 14

Embodiment 14 is method as described in embodiment 13 wherein the load is a Coulomb-type electrostatic chuck. The method further comprises clamping a semiconductor or liquid crystal panel by applying a direct current (DC) high-voltage to the chuck with the power supply.

What is claimed is:

1. A power supply capable of monitoring the impedance or capacitance of a load connected to the power supply,
the power supply including:
a first terminal connectable to the load,
an electric generator adapted for generating a direct current (DC) high-voltage between first and second terminals, wherein the first terminal of the electric generator is connected to the first terminal of the power supply and the second terminal of the electric generator is connected to the ground, and
a monitor,
the monitor comprising:
a inject circuit adapted for flowing an oscillating current between first and second terminals, wherein the first terminal of the inject circuit is connected to the first terminal of the power supply and the second terminal of the inject circuit is connected to the ground or to a second terminal of the power supply;
a boost circuit adapted for generating an oscillating voltage between first and second terminals, wherein the first terminal of the boost circuit is connected to the first terminal of the electric generator and the second terminal of the boost circuit is connected to the first terminal of the power supply;
a sinewave oscillator adapted for generating a sinusoidal voltage at a predetermined frequency, wherein the sinewave oscillator has a terminal that is coupled to one of the inject circuit and the boost circuit;
a current sensor adapted for generating a first alternating signal indicative of the oscillating current;
wherein the current sensor includes a transformer having:
a primary coil in series between the boost circuit and the first terminal of the power supply and
a secondary coil connected to an input of an inverting or non-inverting operational amplifier,
a voltage sensor adapted for generating a second alternating signal indicative of the oscillating voltage;
a source conductor adapted for transmitting a third alternating signal indicative of the sinusoidal voltage; and
a micro-controller coupled to the first alternating signal, the second alternating signal, and the third alternating signal,
wherein the micro-controller is adapted for computing the impedance or capacitance of the load by using digital data derived from the first alternating signal, the second alternating signal, and the third alternating signal.

2. The power supply of claim 1, wherein:
the inject circuit includes a coupling capacitor having one lead connected to the first terminal of the power supply;
the sinewave oscillator has a first terminal connected to another lead of the coupling capacitor and a second terminal connected to the ground or to the second terminal of the power supply,
the boost circuit includes a blocking inductor; and
the blocking inductor is connected between the first terminal of the electric generator and the coupling capacitor.

3. The power supply of claim 1, further comprising an analog demodulator having inputs coupled to the current sensor, the voltage sensor, and the source conductor,
the analog demodulator having outputs coupled to the micro-controller,
the analog demodulator being configured to analogically demodulate the first alternating signal and the second alternating signal relative to the third alternating signal.

4. The power supply of claim 3 wherein the analog demodulator includes a quadratic demodulator configured to generate four output signals:
the magnitude of the first alternating signal multiplied by the cosine of the phase of the first alternating signal relative to the third alternating signal,
the magnitude of the first alternating signal multiplied by the sinus of the phase of the first alternating signal relative to the third alternating signal,
the magnitude of the second alternating signal multiplied by the cosine of the phase of the second alternating signal relative to the third alternating signal, and
the magnitude of the second alternating signal multiplied by the sinus of the phase of the second alternating signal relative to the third alternating signal.

5. The power supply of claim 1, wherein the voltage sensor includes:
a lowpass or bandpass filter connected to the first terminal of the power supply and to the ground, and
an inverting or non-inverting operational amplifier having an input connected to the lowpass or bandpass filter.

6. A method of monitoring the impedance or capacitance of a load connected to a power supply, the power supply including a first terminal connectable to the load, and an electric generator adapted for generating a direct current (DC) high-voltage between first and second terminals, wherein the first terminal of the electric generator is connected to the first terminal of the power supply and the second terminal of the electric generator is connected to the ground, the method comprising:
providing the power supply with a monitor; and
causing the monitor to display or store digital data indicative of the impedance or capacitance of the load;
wherein the monitor includes:
a inject circuit adapted for flowing an oscillating current between first and second terminals, wherein the first terminal of the inject circuit is connected to the first terminal of the power supply and the second terminal of the inject circuit is connected to the ground or to a second terminal of the power supply;
a boost circuit adapted for generating an oscillating voltage between first and second terminals, wherein the first terminal of the boost circuit is connected to the first terminal of the electric generator and the second terminal of the boost circuit is connected to the first terminal of the power supply;
a sinewave oscillator adapted for generating a sinusoidal voltage at a predetermined frequency, wherein the sinewave oscillator has a terminal that is coupled to one of the inject circuit and the boost circuit;
a current sensor adapted for generating a first alternating signal indicative of the oscillating current;
wherein the current sensor includes a transformer having:
a primary coil in series between the boost circuit and the first terminal of the power supply and
a secondary coil connected to an input of an inverting or non-inverting operational amplifier, a voltage sensor adapted for generating a second alternating signal indicative of the oscillating voltage;
a source conductor adapted for transmitting a third alternating signal indicative of the sinusoidal voltage; and
a micro-controller coupled to the first alternating signal, the second alternating signal, and the third alternating signal,
wherein the micro-controller is adapted for computing the impedance or capacitance of the load by using digital data derived from the first alternating signal, the second alternating signal, and the third alternating signal.

7. The method of claim 6, wherein:
the inject circuit includes a coupling capacitor having one lead connected to the first terminal of the power supply;
the sinewave oscillator has a first terminal connected to another lead of the coupling capacitor and a second terminal connected to the ground or to the second terminal of the power supply,
the boost circuit includes a blocking inductor; and
the blocking inductor is connected between the first terminal of the electric generator and the coupling capacitor.

8. The method of claim 6, further comprising an analog demodulator having inputs coupled to the current sensor, the voltage sensor, and the source conductor,
the analog demodulator having outputs coupled to the micro-controller,
the analog demodulator being configured to analogically demodulate the first alternating signal and the second alternating signal relative to the third alternating signal.

9. The method of claim 8 wherein the analog demodulator includes a quadratic demodulator configured to generate four output signals:
the magnitude of the first alternating signal multiplied by the cosine of the phase of the first alternating signal relative to the third alternating signal,
the magnitude of the first alternating signal multiplied by the sinus of the phase of the first alternating signal relative to the third alternating signal,
the magnitude of the second alternating signal multiplied by the cosine of the phase of the second alternating signal relative to the third alternating signal, and
the magnitude of the second alternating signal multiplied by the sinus of the phase of the second alternating signal relative to the third alternating signal.

10. The method of claim 6, wherein the voltage sensor includes
a lowpass or bandpass filter connected to the first terminal of the power supply and to the ground, and
an inverting or non-inverting operational amplifier having an input connected to the lowpass or bandpass filter.

11. The method of claim 6, wherein the load is a Coulomb-type electrostatic chuck, the method further comprising clamping a semiconductor or liquid crystal panel by applying a direct current (DC) high-voltage to the chuck with the power supply.
